(19) United States
(12) Patent Application Publication
(10) Pub. No.: US 2026/0223616 A1
(43) Pub. Date: Jul. 30, 2026

(54) METHODS FOR IMPROVING ETCH PROFILES OF SEMICONDUCTOR DEVICES

(71) Applicant: Tokyo Electron Limited, Tokyo (JP)

(72) Inventors: Kangyi LIN, Albany, NY (US); Hailey JENKINS, Albany, NY (US); Peng WANG, Albany, NY (US)

(73) Assignee: Tokyo Electron Limited, Tokyo (JP)

(21) Appl. No.: 19/040,281

(22) Filed: Jan. 29, 2025

(51) Int. Cl. H01L 21/308; H01L 21/027; H01L 21/033

(52) U.S. Cl. CPC H10P 50/695; H10P 50/692; H10P 76/20; H10P 76/405; H10P 76/4085

(57) ABSTRACT

A method for fabricating semiconductor devices is disclosed. The method includes forming a first hardmask layer over a substrate. The method includes forming a second hardmask layer over the first hardmask layer. The method includes forming an opening extending through the second hardmask layer and the first hardmask layer. The method includes depositing a polymer layer, wherein the polymer layer includes at least a portion in the opening. The method includes etching the substrate using respective remaining portions of the first hardmask layer and the second hardmask layer, together with the polymer layer, as a mask.

### TECHNICAL FIELD

This disclosure generally relates to methods for fabricating semiconductor devices/structures, and more particularly to trimming a dielectric hardmask layer using an ion-free etchant gas for improving an etched profile.

### BACKGROUND

In the manufacture of a semiconductor device, various fabrication processes are executed such as film-forming depositions, etch mask creation, patterning, material etching and removal, and doping treatments. These processes are performed repeatedly to form desired semiconductor device elements on a substrate. While semiconductor devices have scaled down with their feature sizes decreased and aspect ratios increased, such scaling efforts are running into greater challenges as scaling enters single digit nanometer semiconductor device fabrication processes. Although nanoscale semiconductor fabrication processes have been successfully demonstrated and implemented, various embodiments can include numerous operations, and may include increasing stability of semiconductor device element or features.

### SUMMARY

One aspect of the present disclosure is directed to a method for fabricating semiconductor devices. The method includes forming a first hardmask layer over a substrate. The method includes forming a second hardmask layer over the first hardmask layer. The method includes forming an opening extending through the second hardmask layer and the first hardmask layer. The method includes depositing a polymer layer, wherein the polymer layer includes at least a portion in the opening. The method includes etching the substrate using respective remaining portions of the first hardmask layer and the second hardmask layer, together with the polymer layer, as a mask.

In some embodiments, the step of depositing a polymer layer includes flowing at least one of a first precursor or a second precursor, each of the first and second precursors includes carbon, hydrogen, and fluoride. The first precursor includes fluoromethane (CH₃F), and the second precursor includes trifluoromethane (CHF₃).

In some embodiments, the portion of polymer layer extends along an upper portion of a sidewall of the opening, and the polymer layer include an additional portion covering a top surface of the second hardmask layer.

In some embodiments, the portion of polymer layer extends along an upper portion of a sidewall of the opening.

In some embodiments, the portion of the polymer layer overlays a bottom surface of the opening.

In some embodiments, the step of depositing a polymer layer is associated with a fluoride to carbon ratio and a hydrogen to carbon ratio. The fluoride to carbon ratio and the hydrogen to carbon ratio are configured to determine a profile of the polymer layer.

In some embodiments, the first hardmask layer includes a plurality of alternately stacked first and second dielectric layers, and the second hardmask layer include metal carbide.

Another aspect of the present disclosure is directed to a method for fabricating semiconductor devices. The method includes forming a hardmask layer over a substrate. The method includes forming an opening extending through the hardmask layer. The method includes depositing a polymer layer that includes at least a portion extending into the opening. The method includes transferring the opening to the substrate.

In some embodiments, the step of depositing a polymer layer includes flowing at least one of a first precursor or a second precursor, each of the first and second precursors includes carbon, hydrogen, and fluoride. The first precursor includes fluoromethane (CH₃F), and the second precursor includes trifluoromethane (CHF₃).

In some embodiments, the portion of polymer layer extends along an upper portion of a sidewall of the opening, and the polymer layer include an additional portion covering a top surface of the hardmask layer.

In some embodiments, the portion of polymer layer extends along an upper portion of a sidewall of the opening.

In some embodiments, the portion of the polymer layer overlays a bottom surface of the opening.

In some embodiments, the step of depositing a polymer layer is associated with a fluoride to carbon ratio and a hydrogen to carbon ratio. The fluoride to carbon ratio and the hydrogen to carbon ratio are configured to determine a profile of the polymer layer.

Yet another aspect of the present disclosure is directed to a method for fabricating semiconductor devices. The method includes forming a first hardmask layer over a substrate. The method includes forming a second hardmask layer over the first hardmask layer. The method includes forming an opening extending through the second hardmask layer and the first hardmask layer. The method includes depositing a polymer layer by flowing at least one of a first precursor or a second precursor, wherein each of the first and second precursors includes carbon, hydrogen, and fluoride. The method includes etching the substrate using respective remaining portions of the first hardmask layer and the second hardmask layer, together with the polymer layer, as a mask.

In some embodiments, the polymer layer includes at least a portion extending into the opening.

In some embodiments, the first precursor includes fluoromethane (CH₃F), and the second precursor includes trifluoromethane (CHF₃).

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing.

FIG. 1 shows a flow chart of a method for fabricating a semiconductor structure, according to some embodiments.

FIGS. 2A-2E show cross-sectional views of a semiconductor structure, made by the method of FIG. 1, during various fabrication stages, according to some embodiments.

FIGS. 3A-3D show cross-sectional views of the semiconductor structure, following the stage shown in FIG. 2E, during various fabrication stages, according to some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

The present disclosure provides various embodiments of methods for improving an etch profile of one or more underlying metallic layers in a semiconductor device. For example, the underlying meal layer may be configured as one or more access lines (e.g., bit lines, word lines, source lines, etc.) or interconnect structures (e.g., power lines, signal lines, etc.) of the semiconductor device. In some embodiments, the disclosed methods include trimming a dielectric hardmask layer over a metallic layer using an ion-free etchant gas and then etching the metallic layer using the trimmed dielectric hard mask layer as a mask. This allows for additional hardmask margin for etching an underlying metallic layer while preventing metal from re-sputtering on the trimmed dielectric hardmask layer. Accordingly, an etch profile of the underlying metallic layer can be efficiently shrunken. The method described herein can be applied to various metal etch processes and applications, for example in fabrication processes of memory and logic devices.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections and should not be considered limiting to the scope of the claims.

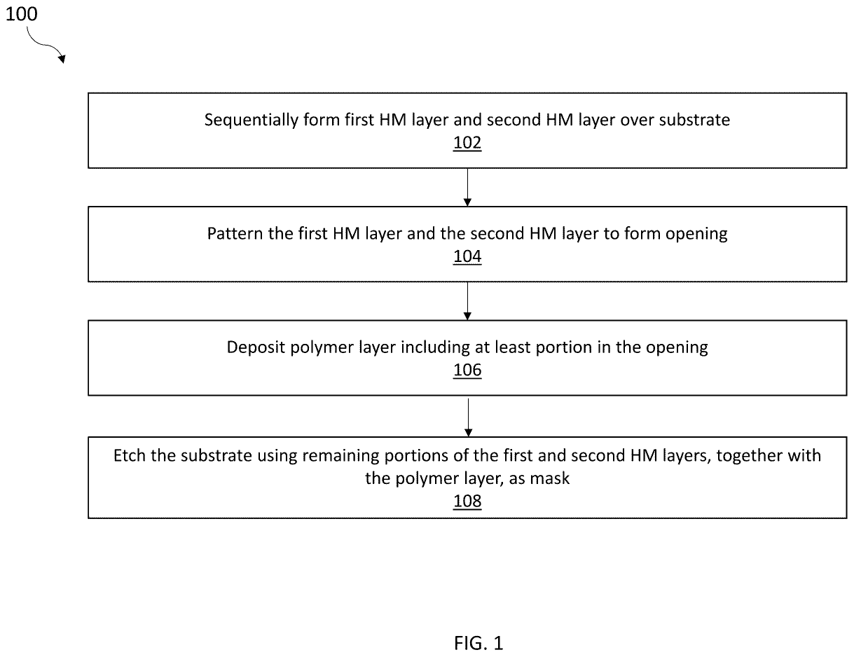

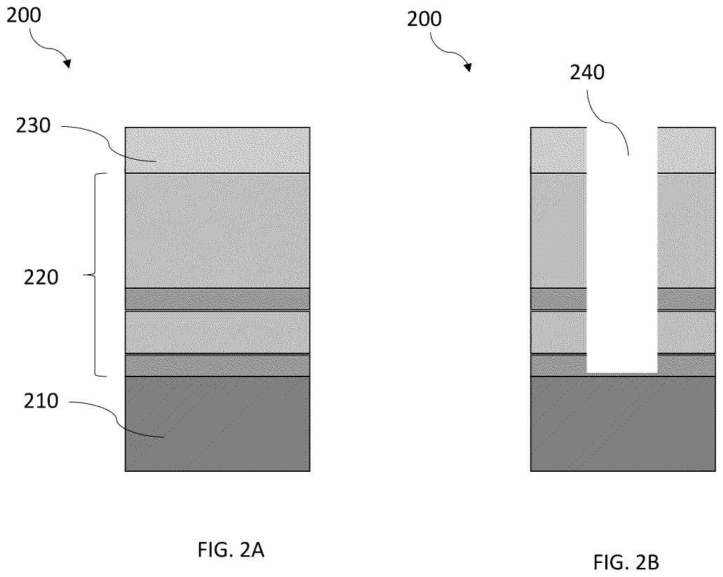

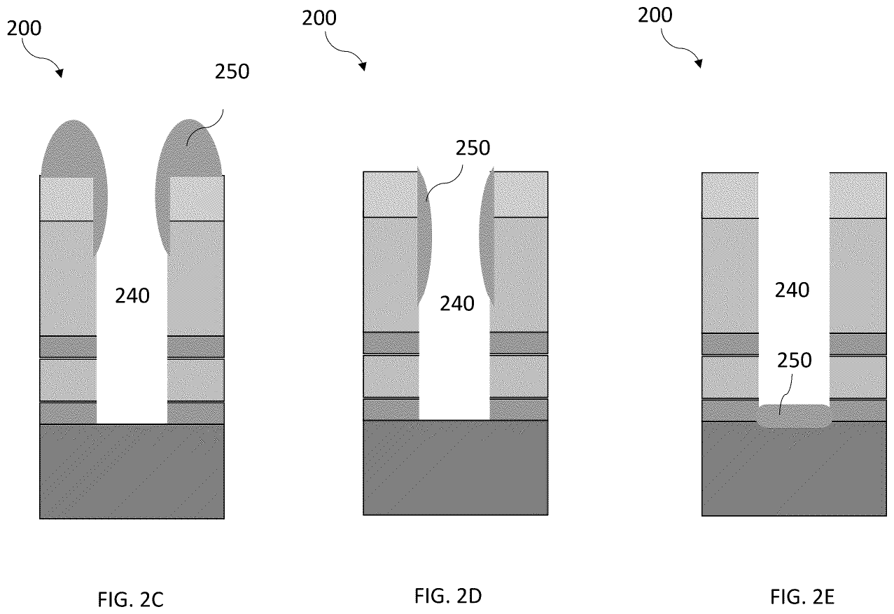

FIG. 1 illustrates a flow chart of a method 100 for fabricating a semiconductor device, in accordance with some embodiments. For example, the method 100 may be utilized to form one or more middle-end-of-line (MEOL) or back-end-of-line (BEOL) features of a semiconductor device. It is noted that the method 100 is merely an example and is not intended to limit the present disclosure. Accordingly, it is understood that additional operations may be provided before, during, and after the method 100 of FIG. 1, that any operation may be omitted, and that some other operations may only be briefly described herein. In various embodiments, operations of the method 100 may be associated with cross-sectional views of example structures at various fabrication stages as shown in FIGS. 2A to 2E, which will be discussed in further detail below. It should be understood that the structure, shown in FIGS. 2A to 2E, may include a number of other structures, while remaining within the scope of the present disclosure.

In brief overview, the method 100 starts with operation 102 of sequentially forming a first hardmask layer and a second hardmask layer over a substrate. The method 100 continues to operation 104 of patterning the first hardmask layer and the second hardmask layer to form an opening extending through the first and second hardmask layers. The method 100 can proceed to operation 106 of depositing a polymer layer including at least a portion in the opening. The method 100 can proceed to operation 108 of etching the substrate using respective remaining portions of the first hardmask layer and the second hardmask layer, together with the polymer layer, as a mask.

Corresponding to operation 102 of FIG. 1, FIG. 2A is a cross-sectional view of a structure 200 in which a first hardmask layer 220 and a second hardmask layer 230 are formed over a substrate 210. In some embodiments, the substrate 210 can include a semiconductor substrate, such as a bulk semiconductor, a semiconductor-on-insulator (SOI) substrate, or the like, which may be doped (e.g., with a p-type or an n-type dopant) or undoped. For example, the substrate 210 may be a wafer, such as a silicon wafer. Other substrates, such as a multi-layered or gradient substrate may also be used. In some other embodiments, the substrate 210 can include at least one of: ruthenium (Ru), copper (Cu), aluminum (Al), or titanium (Ti). The first hardmask layer 220 may include a plural number of dielectric layers alternately stacked on top of one another, where each of the dielectric layers can include a material selected from the group consisting of: silicon oxide (SiO₂), silicon nitride (SiN), silicon oxynitride (SiON), silicon nitride-based material, and combinations thereof. The second hardmask layer 230 may include a metal oxide material, a metal nitride material, or a metal carbide material such as, for example, zirconium (Zr) oxide, titanium (Ti) oxide, tungsten (W) oxide, aluminum (Al) oxide, tungsten (W) carbide, or combinations thereof.

Corresponding to operation 104 of FIG. 1, FIG. 2B is a cross-sectional view of the structure 200 in which the first hardmask layer 220 and the second hardmask layer 230 are patterned to form an opening 240 extending through the first hardmask layer 220 and the second hardmask layer 230. In some embodiments, the first hardmask layer 220 and the second hardmask layer 230 may be patterned through performing a directional or anisotropic etching process. For example, the anisotropic etching process may be a reactive ion etching (RIE) process. In general, the RIE process entails exposing a workpiece to a reactive plasma that may include gases that generate species, such as fluorine, carbon, hydrogen, and molecules and radicals of the combination of these elements. Energetic ion bombardment by species extracted from the RIE plasma can generally have a trajectory normal to a surface of the workpiece that horizontal surfaces are subject to the ion bombardment to the exclusion of other surfaces such as vertical surfaces.

Corresponding to operation 106 of FIG. 1, FIGS. 2C, 2D, and 2E are each a cross-sectional view of the structure 200 in which a polymer layer 250 is formed in the opening 240. In some embodiments, the polymer layer 250 can be formed by flowing at least one of a first precursor or a second precursor into a chamber housing the structure 200, wherein each of the first and second precursors includes carbon, hydrogen, and fluoride. For example, the first precursor includes fluoromethane (CH₃F) and the second precursor includes trifluoromethane (CHF₃).

In some embodiments, a fluoride to carbon ratio and a hydrogen to carbon ratio of the first and second precursors (e.g., CH₃F and CHF₃) can determine a profile of the polymer layer 250. For example, in FIG. 2C where the fluoride to carbon ratio has a lowest value and the hydrogen to carbon ratio has a highest value, the polymer layer 250 can overlay a top surface of the second hardmask layer 230 and further extends downwardly along sidewalls of the opening 240 (or sidewalls of the first hardmask layer 220 and/or second hardmask layer 230); in FIG. 2D where the fluoride to carbon ratio and the hydrogen to carbon ratio each have a medium value, the polymer layer 250 may have no portion disposed on the top surface of the second hardmask layer 230 but a portion extending downwardly along sidewalls of the opening 240 (or sidewalls of the first hardmask layer 220 and/or second hardmask layer 230); and in FIG. 2E where the fluoride to carbon ratio has a highest value and the hydrogen to carbon ratio has a lowest value, the polymer layer 250 may overlay a bottom surface of the opening 240.

As a non-limiting example, to form the profile of the polymer layer 250 shown in FIG. 2C, a high-frequency power of about 200 Watts, a low-frequency of about 120 Watts, a pressure of about 30 millitorr, a flow rate of a first carrier gas (Ar) of about 1100 sccm, a flow rate of a second carrier gas (H₂) of about 100 sccm, a flow rate of the first precursor (CH₃F) of about 55 sccm, and a flow rate of the second precursor (CHF₃) of about 0 sccm may be used in the deposition process. To form the profile of the polymer layer 250 shown in FIG. 2D, a high-frequency power of about 200 Watts, a low-frequency of about 120 Watts, a pressure of about 30 millitorr, a flow rate of a first carrier gas (Ar) of about 1100 sccm, a flow rate of a second carrier gas (H₂) of about 100 sccm, a flow rate of the first precursor (CH₃F) of about 35 sccm, and a flow rate of the second precursor (CHF₃) of about 0 sccm may be used in the deposition process. To form the profile of the polymer layer 250 shown in FIG. 2E, a high-frequency power of about 200 Watts, a low-frequency of about 120 Watts, a pressure of about 30 millitorr, a flow rate of a first carrier gas (Ar) of about 1100 sccm, a flow rate of a second carrier gas (H₂) of about 100 sccm, a flow rate of the first precursor (CH₃F) of about 0 sccm, and a flow rate of the second precursor (CHF₃) of about 25 sccm may be used in the deposition process.

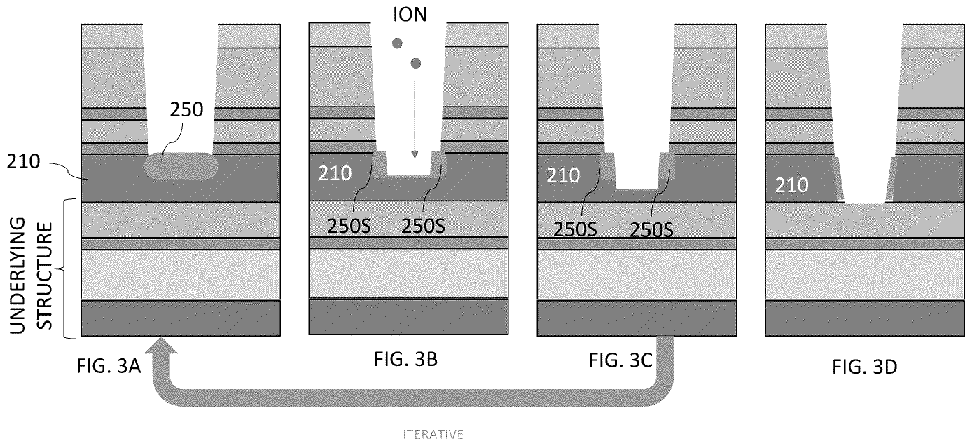

Following operation 106, the method 100 can proceed to operation 108 to etch the substrate with the first hardmask layer 220, the second hardmask layer 230, and the polymer layer 250 as a mask. With the presence of the polymer layer 250, the original opening (e.g., 240) can be trimmed to have a shrunk dimension (e.g., a narrower width or an improved aspect ratio) for forming one or more other features in the substrate 210. FIGS. 3A to 3D illustrate cross-sectional views of the example structure 200 in various fabrication stages, respectively, following the formation of the polymer layer 250 shown in FIG. 2E.

As shown, in FIG. 3A, the polymer layer 250 is formed at the bottom surface of the opening 240, similar to FIG. 2E. Next, an ion-driven etching process can be performed to break through the polymer layer 250. Given anisotropic nature of the ion-driven etching process, certain side portions of the polymer layer 250S may remain, as shown in FIG. 3B. Next, another etching process can be performed to etch the substrate 210 using the remaining side portions of the polymer layer 250S as a mask, as shown in FIG. 3C. In some embodiments, the process steps, respectively corresponding to FIGS. 3A-C, can be iteratively performed until the substrate 210 is punched through, as shown in FIG. 3D. In such embodiments, the substrate 210 may be a middle layer interposed between the first hardmask layer 220 and an underlying structure.

As a non-limiting example, to break through the polymer layer 250 (FIG. 3B), a high-frequency power of about 200 Watts, a low-frequency of about 100 Watts, a pressure of about 20 millitorr, a flow rate of a first carrier gas (Ar) of about 1100 sccm, a flow rate of a second carrier gas (H₂) of about 200 sccm, a flow rate of the first precursor (CH₃F) of about 0 sccm, a flow rate of the second precursor (CHF₃) of about 0 sccm, and a flow rate of nitrogen (N₂) of about 60 sccm may be used in this etching process. To etch the substrate 210 (FIG. 3C), a high-frequency power of about 200 Watts, a low-frequency of about 120 Watts, a pressure of about 30 millitorr, a flow rate of a first carrier gas (Ar) of about 0 sccm, a flow rate of a second carrier gas (H₂) of about 0 sccm, a flow rate of the first precursor (CH₃F) of about 0 sccm, a flow rate of the second precursor (CHF₃) of about 25 sccm, a flow rate of carbon dioxide (CO₂) of about 10 sccm, a flow rate of an etchant gas (e.g., SF₆) of about 5 sccm, and a flow rate of nitrogen (N₂) of about 60 sccm may be used in this etching process.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for fabricating semiconductor devices, comprising:
forming a first hardmask layer over a substrate;
forming a second hardmask layer over the first hardmask layer;
forming an opening extending through the second hardmask layer and the first hardmask layer;
depositing a polymer layer, wherein the polymer layer includes at least a portion in the opening; and
etching the substrate using respective remaining portions of the first hardmask layer and the second hardmask layer, together with the polymer layer, as a mask.

2. The method of claim 1, wherein the step of depositing a polymer layer includes flowing at least one of a first precursor or a second precursor, each of the first and second precursors includes carbon, hydrogen, and fluoride.

3. The method of claim 2, wherein the first precursor includes fluoromethane (CH₃F), and the second precursor includes trifluoromethane (CHF₃).

4. The method of claim 1, wherein the portion of polymer layer extends along an upper portion of a sidewall of the opening, and the polymer layer include an additional portion covering a top surface of the second hardmask layer.

5. The method of claim 1, wherein the portion of polymer layer extends along an upper portion of a sidewall of the opening.

6. The method of claim 1, wherein the portion of the polymer layer overlays a bottom surface of the opening.

7. The method of claim 1, wherein the step of depositing a polymer layer is associated with a fluoride to carbon ratio and a hydrogen to carbon ratio.

8. The method of claim 7, wherein the fluoride to carbon ratio and the hydrogen to carbon ratio are configured to determine a profile of the polymer layer.

9. The method of claim 1, wherein the first hardmask layer includes a plurality of alternately stacked first and second dielectric layers, and the second hardmask layer include metal carbide.

10. A method for fabricating semiconductor devices, comprising:
forming a hardmask layer over a substrate;
forming an opening extending through the hardmask layer;
depositing a polymer layer that includes at least a portion extending into the opening; and
transferring the opening to the substrate.

11. The method of claim 10, wherein the step of depositing a polymer layer includes flowing at least one of a first precursor or a second precursor, each of the first and second precursors includes carbon, hydrogen, and fluoride.

12. The method of claim 11, wherein the first precursor includes fluoromethane (CH₃F), and the second precursor includes trifluoromethane (CHF₃).

13. The method of claim 10, wherein the portion of polymer layer extends along an upper portion of a sidewall of the opening, and the polymer layer include an additional portion covering a top surface of the hardmask layer.

14. The method of claim 10, wherein the portion of polymer layer extends along an upper portion of a sidewall of the opening.

15. The method of claim 10, wherein the portion of the polymer layer overlays a bottom surface of the opening.

16. The method of claim 10, wherein the step of depositing a polymer layer is associated with a fluoride to carbon ratio and a hydrogen to carbon ratio.

17. The method of claim 16, wherein the fluoride to carbon ratio and the hydrogen to carbon ratio are configured to determine a profile of the polymer layer.

18. A method for fabricating semiconductor devices, comprising:
forming a first hardmask layer over a substrate;
forming a second hardmask layer over the first hardmask layer;
forming an opening extending through the second hardmask layer and the first hardmask layer;
depositing a polymer layer by flowing at least one of a first precursor or a second precursor, wherein each of the first and second precursors includes carbon, hydrogen, and fluoride; and
etching the substrate using respective remaining portions of the first hardmask layer and the second hardmask layer, together with the polymer layer, as a mask.

19. The method of claim 18, wherein the polymer layer includes at least a portion extending into the opening.

20. The method of claim 18, wherein the first precursor includes fluoromethane (CH₃F), and the second precursor includes trifluoromethane (CHF₃).
